(19) United States
(12) Patent Application Publication
(10) Pub. No.: US 2016/0020347 A1
(43) Pub. Date: Jan. 21, 2016

(54) BIFACIAL PHOTOVOLTAIC DEVICES

(71) Applicant: Zena Technologies, Inc., Cambridge, MA (US)

(72) Inventors: Young-June Yu, Cranbury, NJ (US); Munib Wober, Topsfield, MA (US)

(21) Appl. No.: 14/334,848

(22) Filed: Jul. 18, 2014

(51) Int. Cl. H01L 31/0352; H01L 31/0232; H02S 50/15; H01L 31/0216

(52) U.S. Cl. CPC H01L 31/03529; H01L 31/02161; H01L 31/02325; H02S 50/15

(57) ABSTRACT

Described herein is a photovoltaic device operable to convert light to electricity, comprising a substrate, a first plurality of structures essentially perpendicular to the substrate and disposed on a first face of the substrate, and a second plurality of structures essentially perpendicular to the substrate and disposed on a second face of the substrate, wherein both the first plurality and the second plurality of structures are configured to convert light to electricity.

### CROSS-REFERENCE TO RELATED APPLICATIONS

This application is related to U.S. patent application Ser. Nos. 12/621,497, 12/633,297, 61/266064, 12/982269, 12/966573, 12/967880, 61/357429, 12/974499, 61/360421, 12/910664, 12/945492, 12/966514, 12/966535, 13/047392, 13/048635, 13/106851, 61/488535, 13/288131, 13/494661, and 13/693207, the disclosures of which are hereby incorporated by reference in their entirety.

### BACKGROUND

A photovoltaic device, also called a solar cell is a solid state device that converts the energy of sunlight directly into electricity by the photovoltaic effect. Assemblies of cells are used to make solar modules, also known as solar panels. The energy generated from these solar modules, referred to as solar power, is an example of solar energy.

The photovoltaic effect is the creation of a voltage (or a corresponding electric current) in a material upon exposure to light. Though the photovoltaic effect is directly related to the photoelectric effect, the two processes are different and should be distinguished. In the photoelectric effect, electrons are ejected from a material's surface upon exposure to radiation of sufficient energy. The photovoltaic effect is different in that the generated electrons are transferred between different bands (i.e. from the valence to conduction bands) within the material, resulting in the buildup of a voltage between two electrodes.

Photovoltaics is a method for generating electric power by using solar cells to convert energy from the sun into electricity. The photovoltaic effect refers to photons of light-packets of solar energy-knocking electrons into a higher state of energy to create electricity. At higher state of energy, the electron is able to escape from its normal position associated with a single atom in the semiconductor to become part of the current in an electrical circuit. These photons contain different amounts of energy that correspond to the different wavelengths of the solar spectrum. When photons strike a PV cell, they may be reflected or absorbed, or they may pass right through. The absorbed photons can generate electricity. The term photovoltaic denotes the unbiased operating mode of a photodiode in which current through the device is entirely due to the light energy. Virtually all photovoltaic devices are some type of photodiode.

### SUMMARY

Described herein is a photovoltaic device operable to convert light to electricity, comprising a substrate, a first plurality of structures essentially perpendicular to the substrate and disposed on a first face of the substrate, and a second plurality of structures essentially perpendicular to the substrate and disposed on a second face of the substrate, wherein both the first plurality and the second plurality of structures are configured to convert light to electricity.

According to an embodiment, the photovoltaic device further comprises a reflective layer disposed on the substrate.

According to an embodiment, the first plurality and second plurality of structures comprise one or more junctions therein or thereon.

According to an embodiment, the one or more junctions are radial junctions.

According to an embodiment, the one or more junctions are conformally disposed on the first plurality and second plurality of structures.

According to an embodiment, the junctions of the first plurality of structures are different from the junctions of the second plurality of structures.

According to an embodiment, the first plurality and the second plurality of structures do not completely overlap.

According to an embodiment, the substrate is an electrically insulating material.

According to an embodiment, the substrate is flexible.

According to an embodiment, the substrate is transparent.

According to an embodiment, the first and second plurality of structures are of the same composition as the substrate.

According to an embodiment, the first and second plurality of structures and the substrate form a single crystal.

According to an embodiment, a top portion of the first and second plurality of structures is rounded or tapered.

According to an embodiment, the one or more junctions are selected from a group consisting of a p-i-n junction, a p-n junction, and a heterojunction.

According to an embodiment, the first plurality and the second plurality of structures comprise nanowires.

According to an embodiment, the photovoltaic device further comprises a cladding layer.

According to an embodiment, reflective layer is non-planar.

According to an embodiment, the photovoltaic device further comprises a cladding layer.

According to an embodiment, the cladding layer is substantially transparent to visible light with a transmittance of at least 50%; the cladding layer is made of an electrically conductive material; the cladding layer is a transparent conductive oxide; the cladding layer is a material selected from a group consisting of indium tin oxide, aluminum doped zinc oxide, zinc indium oxide, Si₃N₄, Al₂O₃, and HfO₂, and zinc tin oxide; the cladding layer has a thickness from 10 nm to 500 nm; and/or the cladding layer is configured as an electrode of the photovoltaic device.

According to an embodiment, the reflective layer is an electrically conductive material; the reflective layer has a reflectance of at least 50% for visible light; the reflective layer has a thickness from about 20 nm to about 500 nm; and/or the reflective layer is an electrode of the photovoltaic device.

According to an embodiment, the photovoltaic device further comprises a surface passivation layer configured to passivate the one or more junctions.

According to an embodiment, one or more junctions comprise an exposed area not covered by the surface passivation layer.

Disclosed herein is a method of converting light to electricity comprising: exposing a photovoltaic device to light, wherein the photovoltaic device comprises a substrate, a first plurality of structures essentially perpendicular to the substrate and disposed on a first face of the substrate, and a second plurality of structures essentially perpendicular to the substrate and disposed on a second face of the substrate; drawing an electrical current from the photovoltaic device.

According to an embodiment, the photo detector is configured to output an electrical signal when exposed to light.

Disclosed herein is a method of detecting light comprises: exposing the photovoltaic device of Claim 1 to light; measuring an electrical signal from the photovoltaic device.

According to an embodiment, the electrical signal is an electrical current, an electrical voltage, an electrical conductance and/or an electrical resistance.

### BRIEF DESCRIPTION OF THE DRAWINGS

FIG. 1 is a schematic cross sectional view of a photovoltaic device according to an embodiment.

FIG. 2 shows more details of the photovoltaic device of FIG. 1, according to an embodiment.

FIG. 3 shows an alternative electrode structure for the photovoltaic device of FIG. 1, according to an embodiment.

FIG. 4 shows exemplary steps for making the photovoltaic device of FIG. 2.

FIG. 5 shows exemplary steps for making the structure of FIG. 3.

FIG. 6 shows alternative stripe-shaped structures of the photovoltaic device.

FIG. 7 shows alternative mesh-shaped structures of the photovoltaic device.

### DETAILED DESCRIPTION

The term “photovoltaic device” as used herein means a device that can generate electrical power by converting light such as solar radiation into electricity. The term “single-crystal” as used herein means that the crystal lattice of the material is continuous and unbroken throughout the entire structures, with essentially no grain boundaries therein. An electrically conductive material can be a material with essentially zero band gap. The electrical conductivity of an electrically conductive material is generally above 10'S/cm. A semiconductor can be a material with a finite band gap up to about 3 eV and general has an electrical conductivity in the range of 10³ to 10⁻⁸ S/cm. An electrically insulating material can be a material with a band gap greater than about 3 eV and generally has an electrical conductivity below 10⁻⁸ S/cm. The term “structures essentially perpendicular to the substrate” as used herein means that angles between the structures and the substrate are from 85° to 90°. The term “cladding layer” as used herein means a layer of substance surrounding the structures. The term “continuous” as used herein means having no gaps, holes, or breaks. The term “coupling layer” as used herein means a layer effective to guide light into the structures.

A group III-V compound material as used herein means a compound consisting of a group III element and a group V element. A group III element can be B, Al, Ga, In, TI, Sc, Y, the lanthanide series of elements and the actinide series of elements. A group V element can be V, Nb, Ta, Db, N, P, As, Sb and Bi. A group II-VI compound material as used herein means a compound consisting of a group II element and a group VI element. A group II element can be Be, Mg, Ca, Sr, Ba and Ra. A group VI element can be Cr, Mo, W, Sg, O, S, Se, Te, and Po. A quaternary material is a compound consisting of four elements.

Described herein is a photovoltaic device operable to convert light to electricity, comprising a substrate, a first plurality of structures essentially perpendicular to the substrate and disposed on a first face of the substrate, a second plurality of structures essentially perpendicular to the substrate and disposed on a second face of the substrate. The first face is opposite to the second face. Both the first plurality and the second plurality of structures are configured to convert light to electricity. The device may have a reflective layer disposed on the substrate. The first plurality and second plurality of structures may have one or more junctions therein or thereon. The junctions may be axial junctions and/or radial junctions. The junctions may also be conformally disposed on the structures. The junctions of the first plurality may be the same or different from the junctions of the second plurality. The first plurality and the second plurality of structures preferably do not completely overlap, or preferably completely do not overlap.

In an embodiment, the substrate is an electrically insulating material. The substrate can comprise glass, polymer, one or more suitable electrically insulating materials, or a combination thereof.

In an embodiment, the substrate is an electrically conductive material. The substrate can comprise one or more metals, one or more suitable electrically insulating material, one or more other electrically conductive materials, or a combination thereof.

In an embodiment, the substrate is flexible. In an embodiment, the substrate is transparent.

In an embodiment, the substrate has a thickness of about 5 μm to about 300 μm, preferably of about 200 μm.

In an embodiment, the structures are cylinders or prisms with a cross-section selected from a group consisting of elliptical, circular, rectangular, and polygonal cross-sections, strips. The one or more structures essentially perpendicular to the substrate may be a mesh. The term “mesh” as used herein means a web-like pattern or construction. In an embodiment, the structures are nanowires. In an embodiment, the structures are microwires. The term “microwire” as used herein means a wire structure with a diameter of 1 μm or more.

In an embodiment, the structures are cylinders with diameters from about 0.2 μm to about 10 μm, preferably with diameters about 1 μm.

In an embodiment, the structures are cylinders or prisms with heights from about 2 μm to about 50 μm, preferably about 10 μm; a center-to-center distance between two closest structures of about 0.5 μm to about 20 μm, preferably about 2 μm.

In an embodiment, the structures are of the same composition as the substrate. In an embodiment, the structures are an electrically insulating material, such as glass, polymer, oxide, or a combination thereof.

In an embodiment, the structures and the substrate form a single crystal, i.e., with essentially no grain boundaries therebetween.

In an embodiment, a top portion of the structures is rounded or tapered. The structures may be rounded or tapered by any suitable method such as isotropic etch. The rounded or tapered top portion can enhance light coupling to the structures.

In an embodiment, the junctions may be selected from a p-i-n junction, a p-n junction, and a heterojunction. In an embodiment, each of these junctions has a thickness of about 5 nm to about 100 nm, preferably about 20 nm.

In an embodiment, an electrically conductive layer may be disposed on areas of the substrate between the structures. This electrically conductive layer may have a thickness of about 5 nm to about 200 nm, preferably about 80 nm. This electrically conductive layer may be transparent, semitransparent, opaque or reflective.

In an embodiment, one of the junctions comprises a heavily doped (p+) semiconductor material layer, a lightly doped (n−) semiconductor material layer, and a heavily doped (n+) semiconductor material layer. The p+ layer, the n− layer and the n+ layer form a p-n junction or heterojunction. The p+ layer, the n− layer and the n+ layer may be different semiconductor materials or the same semiconductor materials. The p+ layer, the n− layer and the n+ layer may be single crystalline, polycrystalline or amorphous.

In an embodiment, one of the junctions comprises a heavily doped (p+) semiconductor material layer, a lightly doped (p−) semiconductor material layer, and a heavily doped (n+) semiconductor material layer. The p+ layer, the p− layer and the n+ layer form a p-n junction or heterojunction. The p+ layer, the p− layer and the n+ layer may be different semiconductor materials or the same semiconductor materials. The p+ layer, the p− layer and the n+ layer may be single crystalline, polycrystalline or amorphous.

In an embodiment, one of the junctions comprises a heavily doped p type (p+) semiconductor material layer, an intrinsic (i) semiconductor layer and a heavily doped n type (n+) semiconductor material layer. The p+ layer, i layer, and the n+ layer form a p-i-n junction. The p+ layer, i layer, and the n+ layer may be single crystalline, polycrystalline (interchangeably referred to as “multicrystalline”), microcrystalline (“pc”) (interchangeably referred to as “nanocrystalline” or “nc”) or amorphous. In an embodiment, the junctions comprise one or more semiconductor materials selected from a group consisting of silicon, germanium, group III-V compound materials, group II-VI compound materials, and quaternary materials.

Nanocrystalline semiconductor, also known as microcrystalline semiconductor, is a form of porous semiconductor. It is an allotropic form of semiconductor with paracrystalline structure—is similar to amorphous semiconductor, in that it has an amorphous phase. Nanocrystalline semiconductor differs from amorphous semiconductor in that nanocrystalline semiconductor has small crystalline grains within the amorphous phase. This is in contrast to polycrystalline semiconductor (e.g., poly-Si) which consists solely of crystalline grains, separated by grain boundaries.

In an embodiment, the band gap of an inner junction (i.e., a junction closer to the structures) is smaller than the band gap of an outer junction (i.e., a junction farther from the structures).

| | | | | 4^{th} junction |
|---|---|---|---|---|
| | 1^{st} junction | | | (conformally |
| | (conformally | 2^{nd} junction | 3^{rd} junction | disposed on the |
| | disposed on and | (conformally | (conformally | 3^{rd} junction and |
| | closest to the | disposed on the | disposed on the | farthest from |
| | structures) | 1^{st} junction) | 2^{nd} junction) | the structures) |
| Two junctions | μc Si p-i-n | amorphous Si | none | none |
| on the | junction | (a-Si) p-i-n | | |
| structures | or | junction | | |
| | μc Ge p-i-n | | | |
| | junction | | | |
| | or | | | |
| | poly-Si p-i-n | | | |
| | junction | | | |
| Three junctions | μc Si p-i-n | amorphous Si | a-Si p-i-n | none |
| on the | junction | (a-SiGe) p-i-n | junction | |
| structures | or | junction | or | |
| | μc Ge p-i-n | | amorphous SiC | |
| | junction | | (a-SiC) p-i-n | |
| | or | | junction | |
| | poly-Si p-i-n | | | |
| | junction | | | |
| Four junctions | μc Ge p-i-n | μc Si p-i-n | a-SiGe p-i-n | a-Si p-i-n |
| on the | junction | junction | junction | junction |
| structures | | | or | or |
| | | | a-Si p-i-n | a-SiC p-i-n |
| | | | junction | junction |

In an embodiment, a cladding layer may be disposed conformally on the outermost junction (i.e., the junction that is among those junctions conformally disposed on the structures and is not between another junction and the structures). A transparent electrically conductive layer may be disposed between the outermost junction and the cladding layer.

The cladding layer is substantially transparent to visible light with a transmittance of at least 50%. The cladding layer may be made of an electrically conductive material or an electrically insulating material. In an embodiment, the cladding layer is a transparent conductive oxide. In an embodiment, the cladding layer is a material selected from a group consisting of indium tin oxide, aluminum doped zinc oxide, zinc indium oxide, and zinc tin oxide. In an embodiment, the cladding layer is a material selected from a group consisting of Si₃N₄, Al₂O₃, and HfO₂. In an embodiment, the cladding layer has a refractive index of about 2. In an embodiment, the cladding layer has a refractive index lower than that of any junctions between the cladding layer and the structures. In an embodiment, the cladding layer has a thickness from about 10 nm to about 500 nm, preferably about 200 nm. In an embodiment, the cladding layer is configured as an electrode of the photovoltaic device.

According to an embodiment, a reflective layer is disposed in a plurality of recesses between the structures and the reflective layer is above the junctions. The reflective layer may be a material selected from a group consisting of Ni, Pt, Al, Au, Ag, Pd, Cr, Cu, Ti, and a combination thereof. The reflective layer is preferably an electrically conductive material such as a metal. The reflective layer preferably has a reflectance (i.e., the fraction of incident electromagnetic power that is reflected) of at least 50% for visible light (i.e., light have a wavelength from 390 to 750 nm) of any wavelength. The reflective layer has a thickness of at least 5 nm, preferably from about 20 nm to about 500 nm (e.g., about 200 nm). The reflective layer in the plurality of recesses is preferably connected. The reflective layer is functional to reflect light incident thereon to the structures so that the light is absorbed by the structures; and/or the reflective layer is functional as an electrode of the photovoltaic device. The reflective layer is preferably non-planar. The term “electrode” as used herein means a conductor used to establish electrical contact with the photovoltaic device.

According to an embodiment, a metal layer is disposed in a plurality of recesses between the structures, and the metal layer is between the junctions and the structures. The metal layer may be a material selected from a group consisting of Ni, Pt, Al, Au, Ag, Pd, Cr, Cu, Ti, and a combination thereof. The metal layer has a thickness of at least 5 nm, preferably from about 20 nm to about 500 nm (e.g., about 200 nm). The metal layer in the plurality of recesses is preferably connected. The metal layer is preferably planar. The metal layer is functional as an electrode of the photovoltaic device.

In an embodiment, space between the structures may be filled with a filler material such as a polymer. The filler material preferably is transparent and/or has a low refractive index. In an embodiment, a top surface of the filler material comprises one or more microlenses configured to concentrate incident light on the photovoltaic device onto the structures.

In an embodiment, a method of making the photovoltaic device comprises: generating a pattern of openings in a resist layer using a lithography technique, wherein locations and shapes of the openings correspond to location and shapes of the structures; forming the structures and regions therebetween by etching the substrate; depositing the reflective layer to the bottom wall. A resist layer as used herein means a thin layer used to transfer a pattern to the substrate, which the resist layer is deposited upon. A resist layer can be patterned via lithography to form a (sub)micrometer-scale, temporary mask that protects selected areas of the underlying substrate during subsequent processing steps. The resist is generally proprietary mixtures of a polymer or its precursor and other small molecules (e.g. photoacid generators) that have been specially formulated for a given lithography technology. Resists used during photolithography are called photoresists. Resists used during e-beam lithography are called e-beam resists. A lithography technique can be photolithography, e-beam lithography, holographic lithography. Photolithography is a process used in microfabrication to selectively remove parts of a thin film or the bulk of a substrate. It uses light to transfer a geometric pattern from a photo mask to a light-sensitive chemical photo resist, or simply “resist,” on the substrate. A series of chemical treatments then engraves the exposure pattern into the material underneath the photo resist. In complex integrated circuits, for example a modern CMOS, a wafer will go through the photolithographic cycle up to 50 times. E-beam lithography is the practice of scanning a beam of electrons in a patterned fashion across a surface covered with a film (called the resist), (“exposing” the resist) and of selectively removing either exposed or non-exposed regions of the resist (“developing”). The purpose, as with photolithography, is to create very small structures in the resist that can subsequently be transferred to the substrate material, often by etching. It was developed for manufacturing integrated circuits, and is also used for creating nanotechnology artifacts.

In an embodiment, the structures and regions therebetween are formed by deep etch followed by isotropic etch. A deep etch is a highly anisotropic etch process used to create deep, steep-sided holes and trenches in wafers, with aspect ratios of often 20:1 or more. An exemplary deep etch is the Bosch process. The Bosch process, also known as pulsed or time-multiplexed etching, alternates repeatedly between two modes to achieve nearly vertical structures: 1. a standard, nearly isotropic plasma etch, wherein the plasma contains some ions, which attack the wafer from a nearly vertical direction (For silicon, this often uses sulfur hexafluoride (SF₆)); 2. deposition of a chemically inert passivation layer (for instance, C₄F₈ source gas yields a substance similar to Teflon). Each phase lasts for several seconds. The passivation layer protects the entire substrate from further chemical attack and prevents further etching. However, during the etching phase, the directional ions that bombard the substrate attack the passivation layer at the bottom of the trench (but not along the sides). They collide with it and sputter it off, exposing the substrate to the chemical etchant. These etch/deposit steps are repeated many times over resulting in a large number of very small isotropic etch steps taking place only at the bottom of the etched pits. To etch through a 0.5 mm silicon wafer, for example, 100-1000 etch/deposit steps are needed. The two-phase process causes the sidewalls to undulate with an amplitude of about 100-500 nm. The cycle time can be adjusted: short cycles yield smoother walls, and long cycles yield a higher etch rate. Isotropic etch is non-directional removal of material from a substrate via a chemical process using an etchant substance. The etchant may be a corrosive liquid or a chemically active ionized gas, known as a plasma.

In an embodiment, a method of converting light to electricity comprises: exposing the photovoltaic device to light; drawing an electrical current from the photovoltaic device. The electrical current can be drawn from the wavelength-selective layer.

In an embodiment, a photo detector comprises the photovoltaic device, wherein the photo detector is configured to output an electrical signal when exposed to light.

In an embodiment, a method of detecting light comprises exposing the photovoltaic device to light; measuring an electrical signal from the photovoltaic device. The electrical signal can be an electrical current, an electrical voltage, an electrical conductance and/or an electrical resistance. A bias voltage is applied to the structures in the photovoltaic device.

In an embodiment, photovoltaic devices produce direct current electricity from sun light, which can be used to power equipment or to recharge a battery. A practical application of photovoltaics was to power orbiting satellites and other spacecraft, but today the majority of photovoltaic modules are used for grid connected power generation. In this case an inverter is required to convert the DC to AC. There is a smaller market for off-grid power for remote dwellings, boats, recreational vehicles, electric cars, roadside emergency telephones, remote sensing, and cathodic protection of pipelines. In most photovoltaic applications the radiation is sunlight and for this reason the devices are known as solar cells. In the case of a p-n junction solar cell, illumination of the material results in the creation of an electric current as excited electrons and the remaining holes are swept in different directions by the built-in electric field of the depletion region. Solar cells are often electrically connected and encapsulated as a module. Photovoltaic modules often have a sheet of glass on the front (sun up) side, allowing light to pass while protecting the semiconductor wafers from the elements (rain, hail, etc.). Solar cells are also usually connected in series in modules, creating an additive voltage. Connecting cells in parallel will yield a higher current. Modules are then interconnected, in series or parallel, or both, to create an array with the desired peak DC voltage and current.

In an embodiment, the photovoltaic device can also be associated with buildings: either integrated into them, mounted on them or mounted nearby on the ground. The photovoltaic device can be retrofitted into existing buildings, usually mounted on top of the existing roof structure or on the existing walls. Alternatively, the photovoltaic device can be located separately from the building but connected by cable to supply power for the building. The photovoltaic device can be used as as a principal or ancillary source of electrical power. The photovoltaic device can be incorporated into the roof or walls of a building.

In an embodiment, the photovoltaic device can also be used for space applications such as in satellites, spacecrafts, space stations, etc. The photovoltaic device can be used as main or auxiliary power sources for land vehicles, marine vehicles (boats) and trains. Other applications include road signs, surveillance cameras, parking meters, personal mobile electronics (e.g., cell phones, smart phones, laptop computers, personal media players).

### Examples

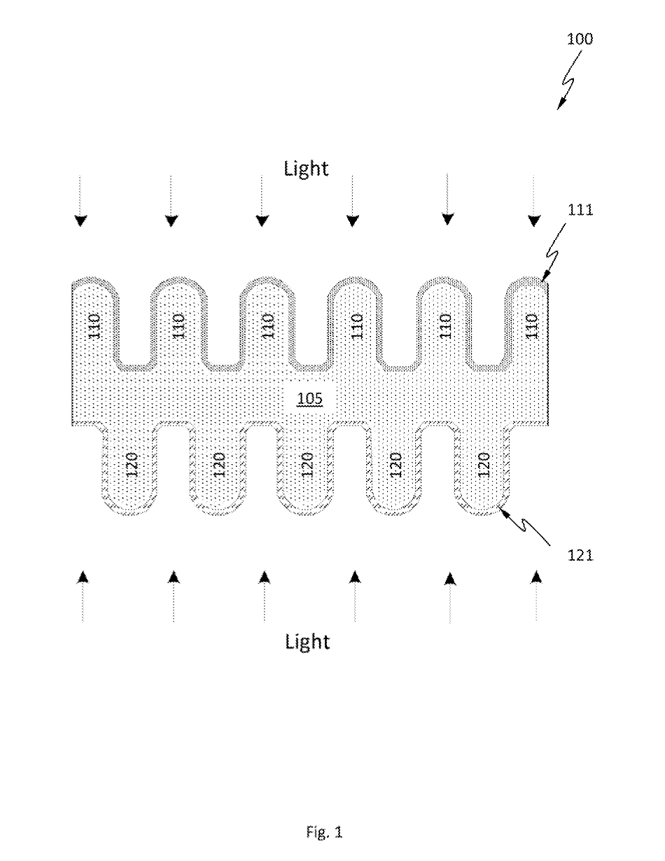

FIG. 1 shows a schematic cross-section of a photovoltaic device 100, according to an embodiment. Certain optional features are omitted from FIG. 1 for clarity. The photovoltaic device 100 comprises a substrate 105, a first plurality of structures 110 essentially perpendicular to the substrate 105 and disposed on one face of the substrate 105, and a second plurality of structures 120 essentially perpendicular to the substrate 105 and disposed on an opposite face of the substrate 105. The structures 110 and 120 may have one or more junctions 111 and 121 thereon or therein. The junctions 111 and 121 may be selected from those in Table 1. The first plurality and the second plurality of structure preferably do not completely overlap, or preferably completely do not overlap.

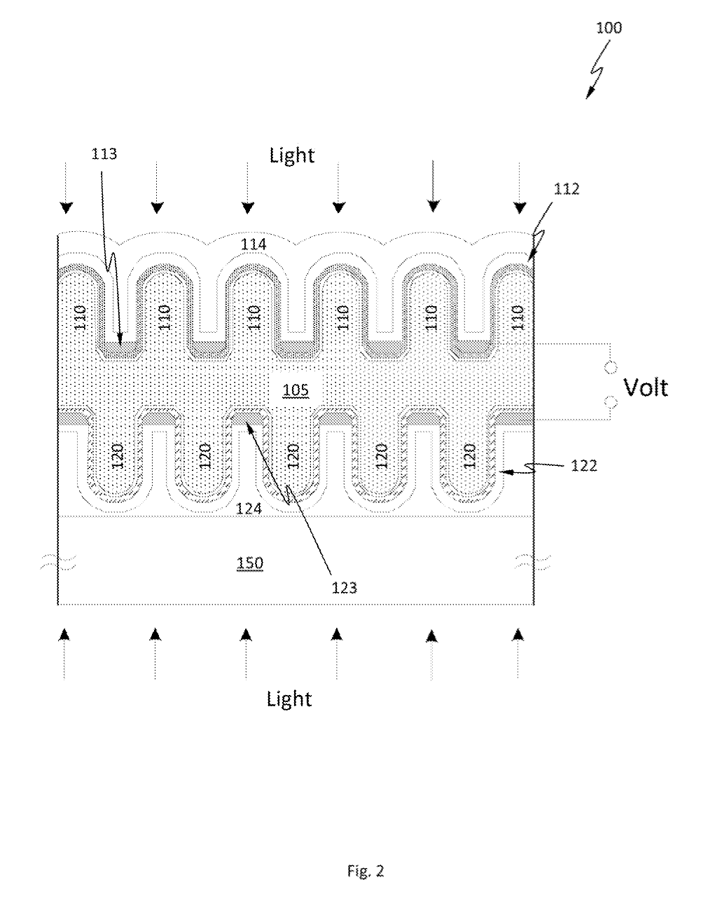

FIG. 2 shows more details of the photovoltaic device 100, according to an embodiment. A cladding layer 112 and a cladding layer 122 may be respectively conformally disposed on the junctions 111 and 121. A reflective layer 113 and a reflective layer 123 may be respectively disposed in a plurality of recesses between the structures 110 and in a plurality of recesses between the structures 120. The reflective layers 113 and 123 may be electrically conductive and function as electrodes of the photovoltaic device 100. Gaps between the structures 110 and between the structures 120 may be filled with filler materials 114 and 124, respectively. The substrate 105 may be thinned and supported on a transparent support substrate 150.

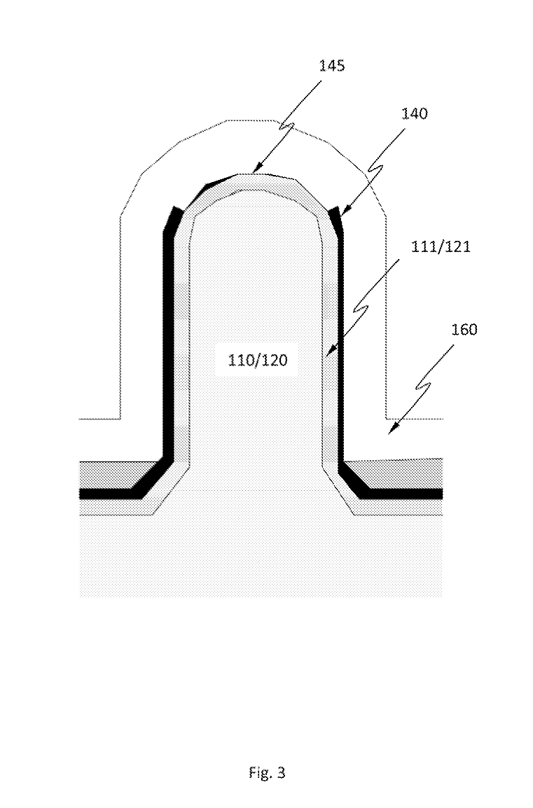

FIG. 3 shows an alternative electrode structure for the photovoltaic device 100, according to an embodiment. The junctions 111 and 121 may have a surface passivation layer 140 thereon. The surface passivation layer 140 is configured to passivate the junctions. The terms “passivation” and “passivate” as used herein means a process of eliminating dangling bonds (i.e., unsatisfied valence on immobilized atoms). The junctions 111 and 121 may have an exposed area 145, not covered by the surface passivation layer 140. An electrical conductive layer 160 may be in electrical contact with the junctions 111 and 121 through the exposed area 145. The electrical conductive layer 160 may be transparent.

In one embodiment, the structures 110/120 may be arranged in an array, such as a rectangular array, a hexagonal array, a square array, concentric ring.

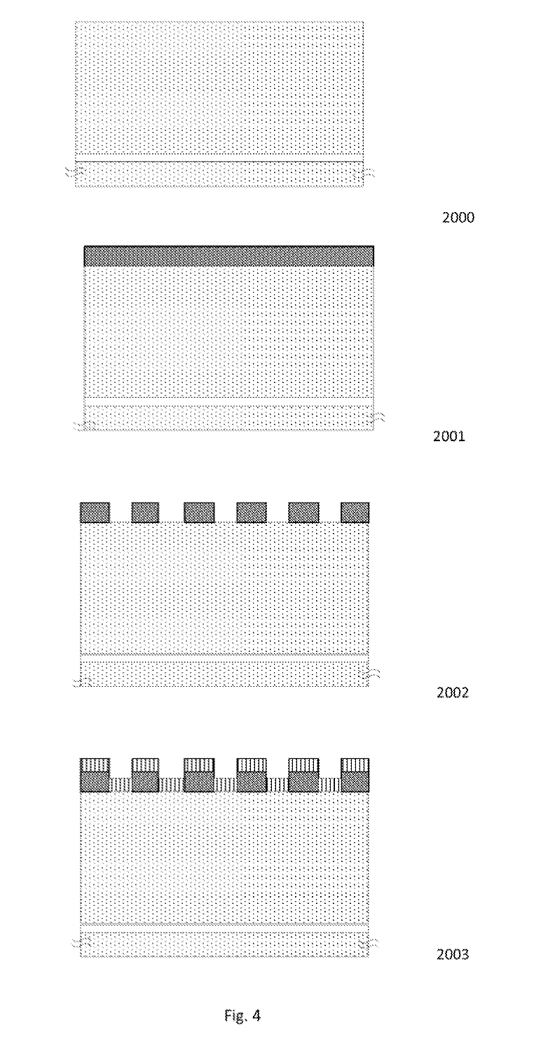

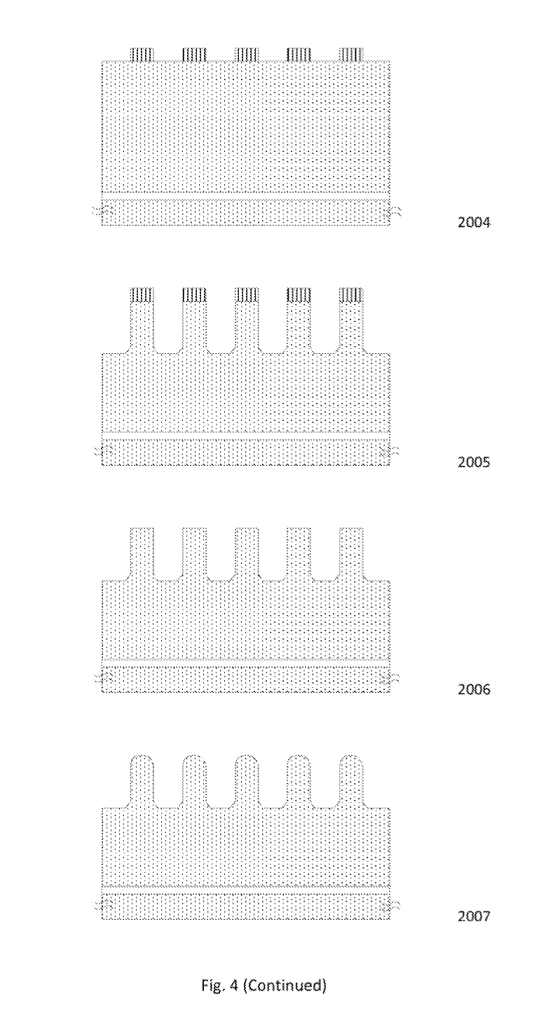

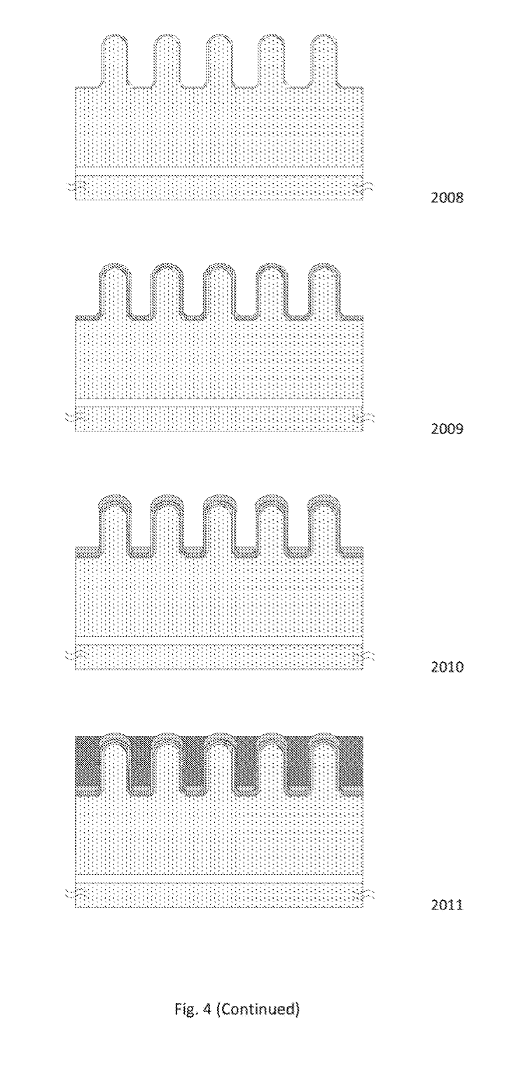

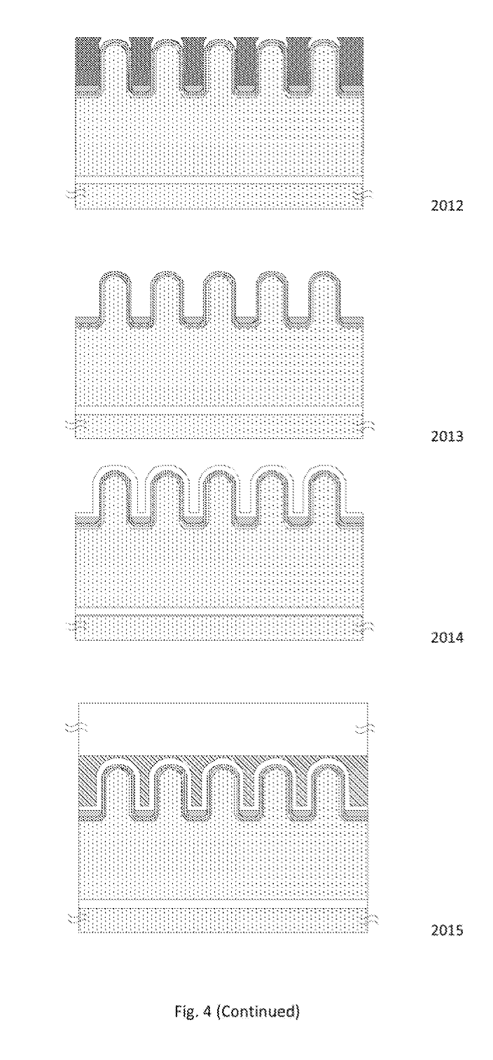

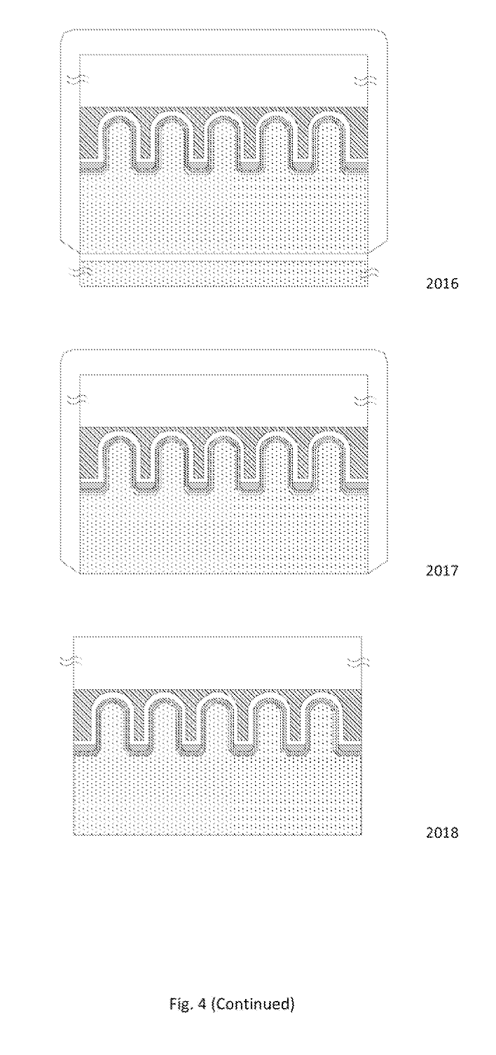

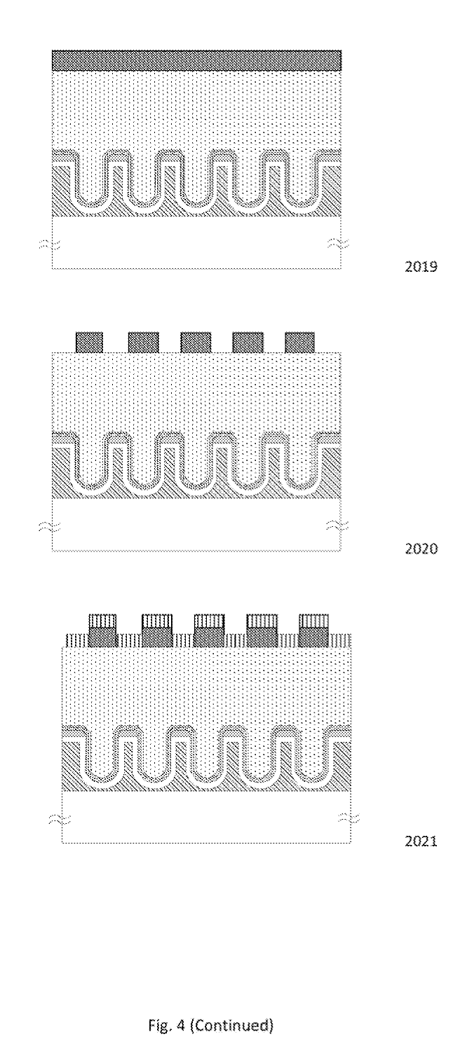

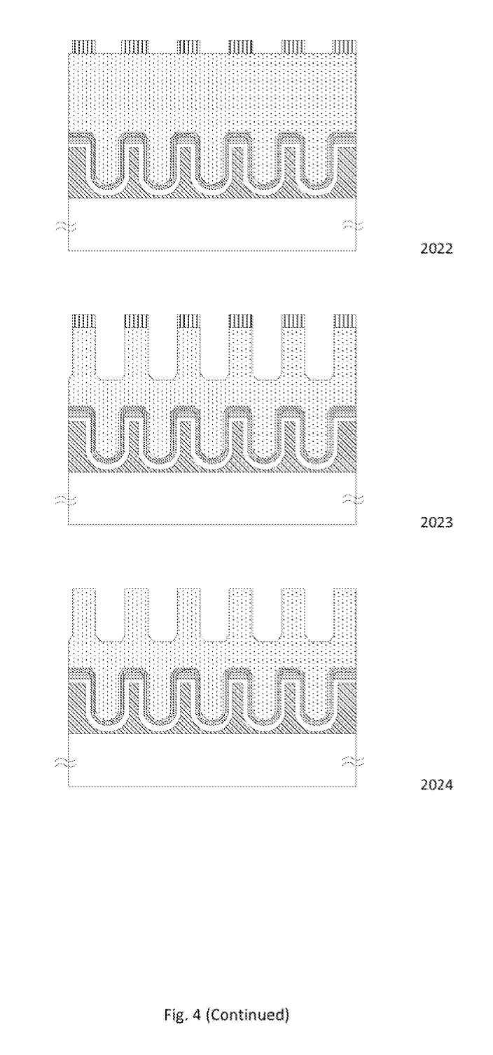

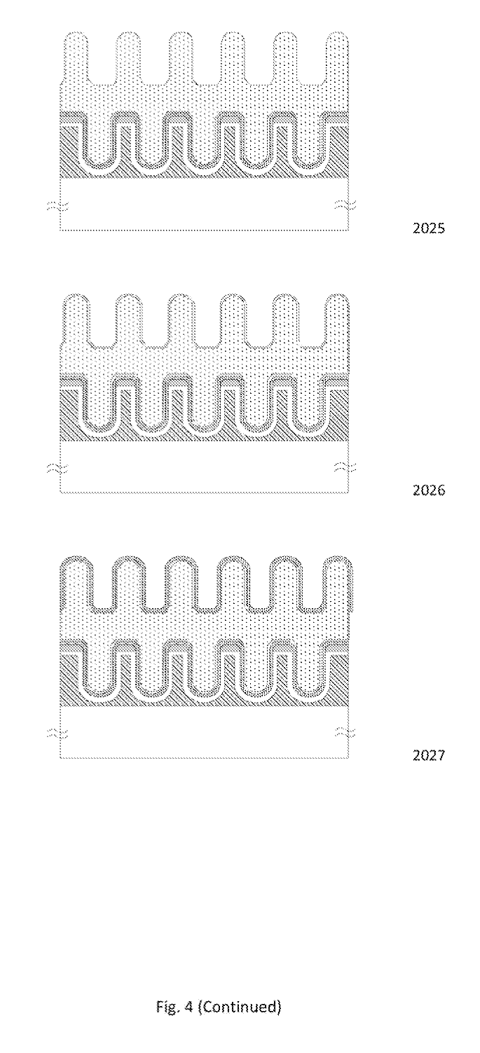

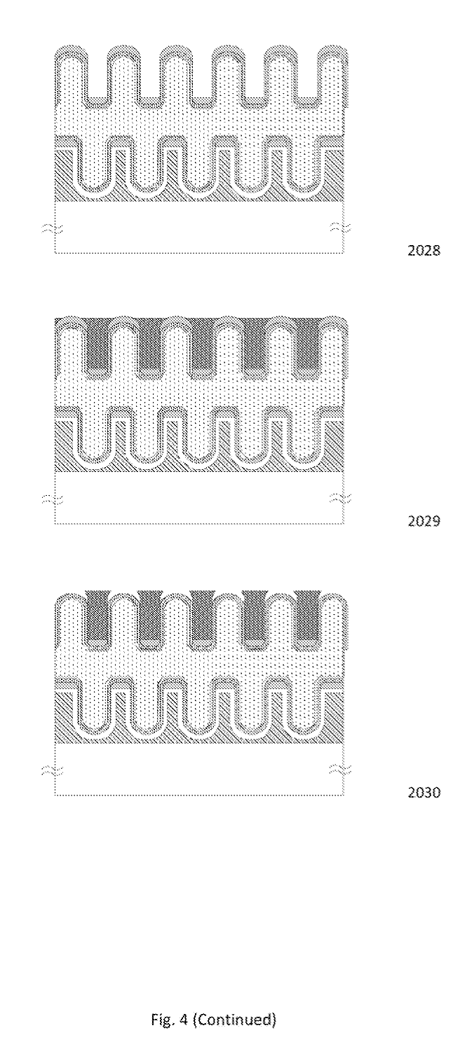

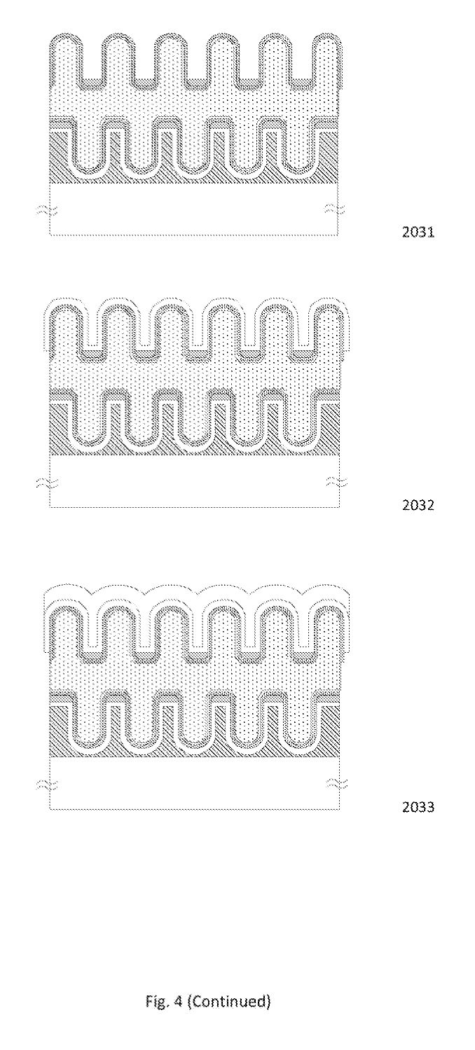

A method of making the photovoltaic device 100 as shown in FIG. 2, according to an embodiment, comprises the following steps as shown in FIG. 4:

In step 2000, an 501 substrate is provided. The SOI substrate may have a lightly doped silicon device layer, a buried oxide and a thick handling silicon layer at the bottom. The device layer can be either p type or n type. In this example, n-type SOI wafer is used. Thickness of the n-type layer is typically 30 μm.

In step 2001, a resist layer is applied to the substrate. The resist layer can be applied by spin coating. The resist layer can be a photo resist or an e-beam resist.

In step 2002, lithography is performed. The resist layer now has a pattern of openings in which the substrate is exposed. The resolution of the lithography is limited by the wavelength of the radiation used. Photolithography tools using deep ultraviolet (DUV) light with wavelengths of approximately 248 and 193 nm, allows minimum feature sizes down to about 50 nm. E-beam lithography tools using electron energy of 1 keV to 50 keV allows minimum feature sizes down to a few nanometers.

In step 2003, a mask layer is deposited over the remaining portion of the resist layer and the exposed portion of the substrate. The mask layer can be deposited using any suitable method such as thermal evaporation, e-beam evaporation, sputtering. The mask layer can be a metal such as Cr or Al, or a dielectric such as SiO₂ or Si₃N₄. The thickness of the mask layer can be determined by a height of the structures 110 and etching selectivity (i.e., ratio of etching rates of the mask layer and the substrate).

In step 2004, remainder of the resist layer is lift off by a suitable solvent or ashed in a resist asher.

In step 2005, the exposed portion of the substrate is deep etched to a desired depth, to form the structures 110.

In step 2006, the mask layer is removed by a suitable such as wet etching with suitable etchant, ion milling, sputtering.

In step 2007, a top portion of the structures 110 is rounded or tapered using a suitable technique such as dry etch or wet etch.

In step 2008, an intrinsic a-Si layer or an oxide layer is deposited using ALD (atomic layer deposition) onto the structures 110. Other methods including PECVD, CVD can also be used.

In step 2009, a heavily doped (e.g., n+) a-Si layer or a heavily doped poly-silicon layer is deposited. The heavily doped a-Si layer plus the intrinsic a-Si layer, or the heavily doped poly-silicon layer plus the oxide layer, and the structures 110 form the junction 111.

In step 2010, a reflective layer is deposited between the structures 110, and above the junction 111.

In step 2011, a resist layer is applied to the substrate. The resist layer can be applied by spin coating. The resist layer can be a photo resist or an e-beam resist. The resist layer is briefly etched so that the reflective layer above the junction 111 is exposed.

In step 2012, the reflective layer above the junction 111 is removed using a suitable method such as etching.

In step 2013, the resist layer is lift off by a suitable solvent or ashed in a resist asher.

In step 2014, the cladding layer is conformally deposited on the structures 110. The cladding layer may be a transparent electrically conductive material such as doped ZnO or MgF₂. Subsequently, the substrate may be annealed in forming gas at 200′C for 30 minutes.

In step 2015, an optically transparent substrate is attached to the structures 110, to provide mechanical support as well as heat conduction, with a transparent heat conductive glue. The optically transparent substrate can be a glass or a plastic substrate.

In step 2016, a protecting layer is conformally deposited such that only the thick handling silicon layer and the buried oxide are not covered. The protecting layer may be a wax or a polymer that is resistant to wet etching of silicon.

In step 2017, the thick handling silicon layer is removed by wet etching (e.g., with KOH). The buried oxide layer is subsequently removed by another wet etch by buffered HF solution.

In step 2018, the protecting layer is removed.

In step 2019, a resist layer is applied to the substrate on a face opposite to the structures 110. The resist layer can be applied by spin coating. The resist layer can be a photo resist or an e-beam resist.

In step 2020, lithography is performed. The resist layer now has a pattern of openings in which the substrate is exposed.

In step 2021, a mask layer is deposited over the remaining portion of the resist layer and the exposed portion of the substrate. The mask layer can be deposited using any suitable method such as thermal evaporation, e-beam evaporation, sputtering. The mask layer can be a metal such as Cr or Al, or a dielectric such as SiO₂ or Si₃N₄. The thickness of the mask layer can be determined by a height of the structures 120 and etching selectivity (i.e., ratio of etching rates of the mask layer and the substrate).

In step 2022, remainder of the resist layer is lift off by a suitable solvent or ashed in a resist asher.

In step 2023, the exposed portion of the substrate is deep etched to a desired depth, to form the structures 120.

In step 2024, the mask layer is removed by a suitable such as wet etching with suitable etchant, ion milling, sputtering.

In step 2025, a top portion of the structures 120 is rounded or tapered using a suitable technique such as dry etch or wet etch.

In step 2026, an intrinsic a-Si layer or an oxide layer is deposited using ALD onto the structures 120. Other methods including PECVD, CVD can also be used.

In step 2027, a heavily doped (e.g., p+) a-Si layer or a heavily doped poly-silicon layer is deposited. The heavily doped a-Si layer plus the intrinsic a-Si layer, or the heavily doped poly-silicon layer plus the oxide layer, and the structures 120 form the junction 121.

In step 2028, a reflective layer is deposited between the structures 120, and above the junction 121.

In step 2029, a resist layer is applied to the substrate. The resist layer can be applied by spin coating. The resist layer can be a photo resist or an e-beam resist. The resist layer is briefly etched so that the reflective layer above the junction 121 is exposed.

In step 2030, the reflective layer above the junction 121 is removed using a suitable method such as etching.

In step 2031, the resist layer is lift off by a suitable solvent or ashed in a resist asher.

In step 2032, the cladding layer is conformally deposited on the structures 120. The cladding layer may be a transparent electrically conductive material such as doped ZnO or MgF₂. Subsequently, the substrate may be annealed in forming gas at 200° C. for 30 minutes.

In optional step 2033, a low refractive index optically transparent polymer material is deposited to fill the space between the structures 110.

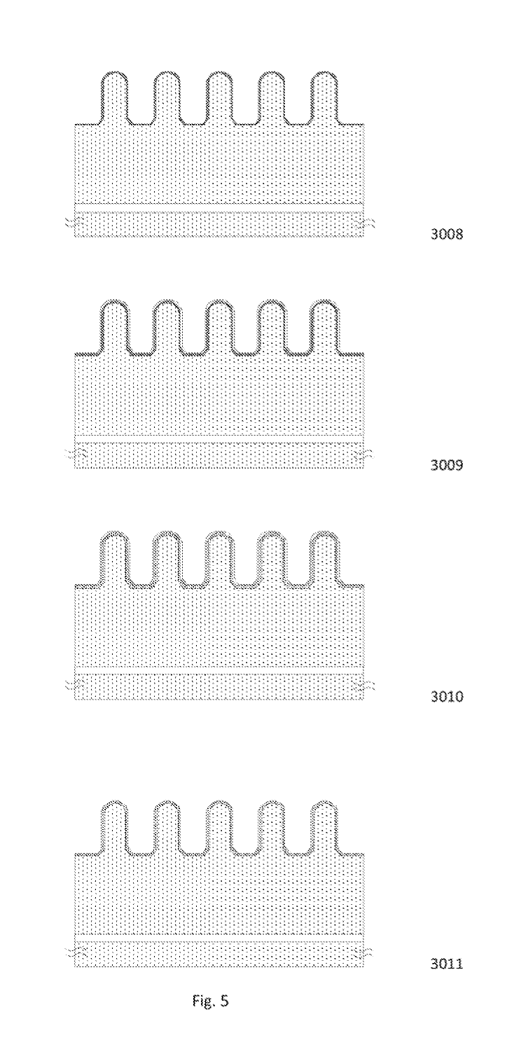

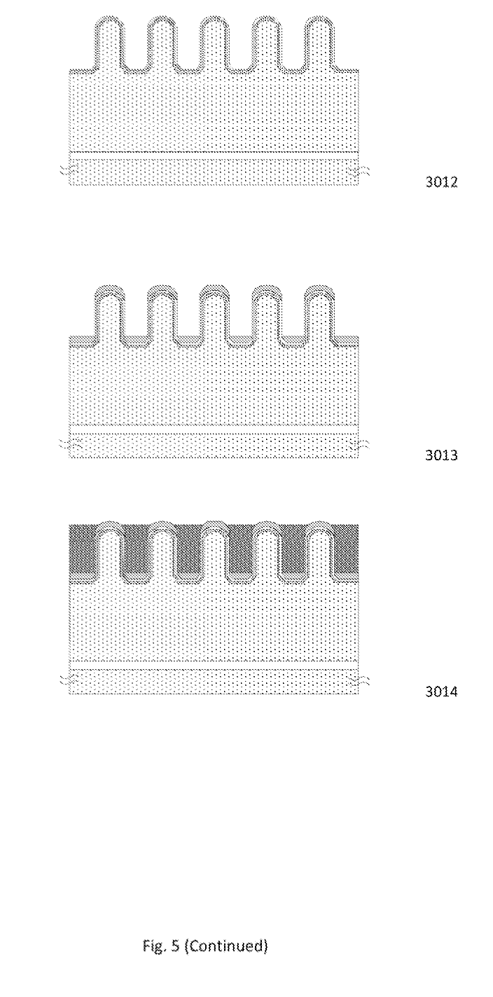

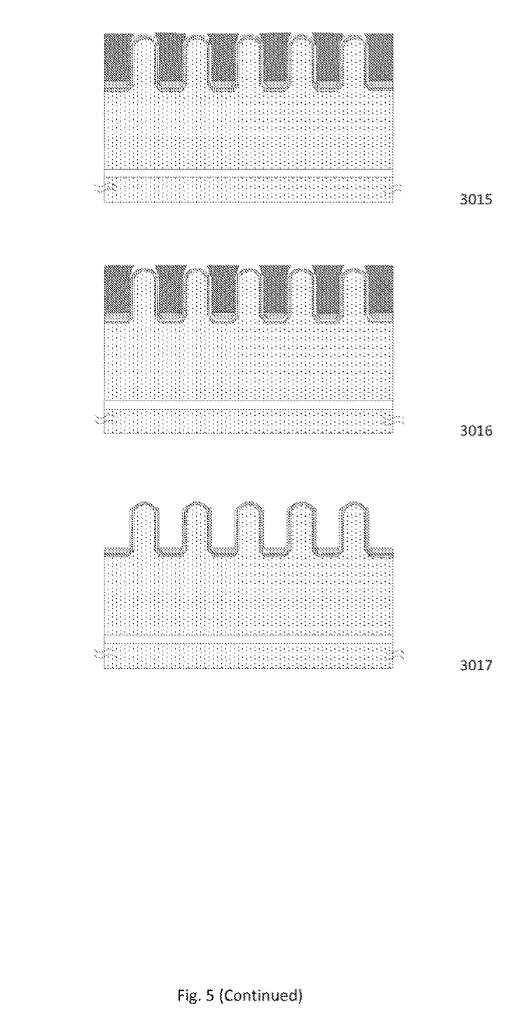

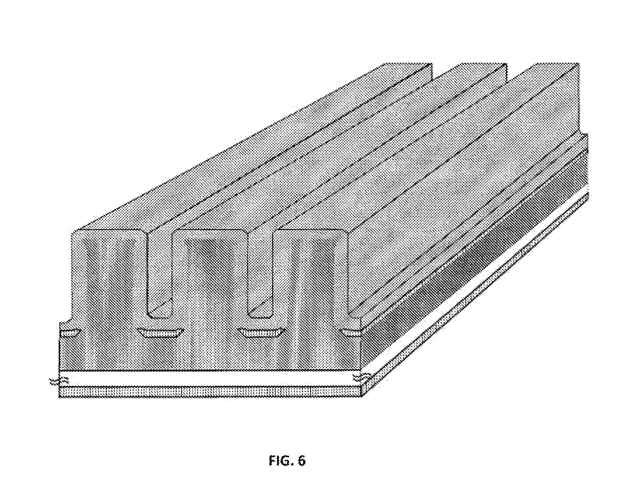

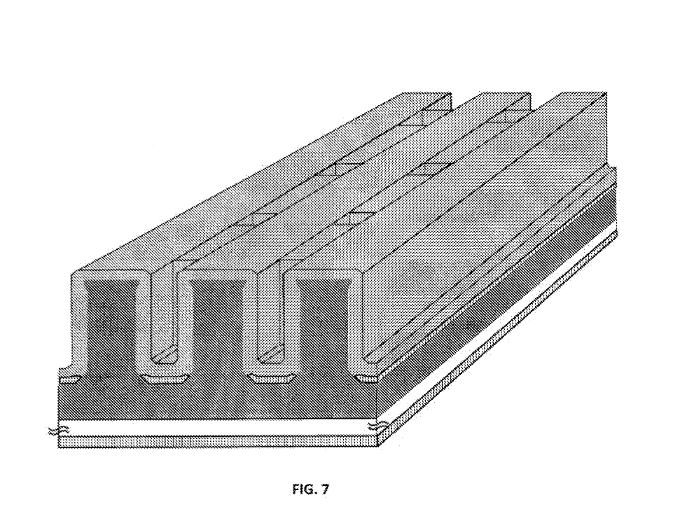

To make the structure as shown in FIG. 3, steps 2008-2013 may be replaced by the following steps as shown in FIG. 5:

In step 3008, a thin dopant layer is conformally deposited on the structures 110. The dopant layer can be deposited either by a suitable technique such as ALD, or CVD.

The ALD technique is preferred because of low temperature and low damage deposition properties. The dopant layer can comprise any suitable material such as trimethylboron, triisopropylborane ((C₃H₇)₃B), triethoxyborane ((C₂H₅O)₃B, and/or triisopropoxyborane ((C₃H₇O)₃B. More details can be found in an abstract of a presentation titled “Atomic layer deposition of boron oxide as dopant source for shallow doping of silicon” by Bodo Kalkofen and Edmund P. Burte in the 218th Electrochemical Society Meeting, Oct. 10, 2010-Oct. 15, 2010, which is hereby incorporated by reference in its entirety.

In step 3009, a shield layer is deposited conformally by ALD onto the dopant layer to prevent the dopant layer from evaporation during thermal diffusion in step 3010.

In step 3010, the device is thermally annealed for 30 minutes at 850° C. to drive the dopant into the surface of the structures 110 and to form the junction 111 at the surface of the structures 110.

In step 3011, any oxide at the surface of structures 110 are removed by wet etch with buffered HF.

In step 3012, a passivation layer is deposited by either ALD, or PECVD, or dry oxidation process. The passivation layer may be an oxide layer such as HfO₂, SiO_{z}, and Al₂O₃.

In step 3013, a reflective layer is deposited between the structures 110, and above the junction 111.

In step 3014, a resist layer is applied to the substrate. The resist layer can be applied by spin coating. The resist layer can be a photo resist or an e-beam resist. The resist layer is briefly etched so that the reflective layer above the junction 111 is exposed.

In step 3015, the reflective layer above the junction 111 is removed using a suitable method such as etching.

In step 3016, any exposed portion of the passivation layer is removed.

In step 3017, the resist layer is lift off by a suitable solvent or ashed in a resist asher.

A method of converting light to electricity comprises: exposing both faces of the photovoltaic device 100 to light; absorbing the light and converting the light to electricity using the structures 110 and 120; drawing an electrical current from the photovoltaic device 100. The electrical current can be drawn from the reflective layer 113 and the reflective layer 123.

A photo detector according to an embodiment comprises the photovoltaic device 100, wherein the photo detector is configured to output an electrical signal when exposed to light.

A method of detecting light comprises: exposing the photovoltaic device 100 to light; measuring an electrical signal from the photovoltaic device 100. The electrical signal can be an electrical current, an electrical voltage, an electrical conductance and/or an electrical resistance.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

What is claimed is:

1. A photovoltaic device operable to convert light to electricity, comprising a substrate, a first plurality of structures essentially perpendicular to the substrate and disposed on a first face of the substrate, and a second plurality of structures essentially perpendicular to the substrate and disposed on a second face of the substrate, wherein both the first plurality and the second plurality of structures are configured to convert light to electricity.

2. The photovoltaic device of claim 1, further comprising a reflective layer disposed on the substrate.

3. The photovoltaic device of claim 1, wherein the first plurality and second plurality of structures comprise one or more junctions therein or thereon.

4. The photovoltaic device of claim 3, wherein the one or more junctions are radial junctions.

5. The photovoltaic device of claim 3, wherein the one or more junctions are conformally disposed on the first plurality and second plurality of structures.

6. The photovoltaic device of claim 3, wherein the junctions of the first plurality of structures are different from the junctions of the second plurality of structures.

7. The photovoltaic device of claim 1, wherein the first plurality and the second plurality of structures do not completely overlap.

8. The photovoltaic device of claim 1, wherein the substrate is an electrically insulating material.

9. The photovoltaic device of claim 1, wherein the substrate is flexible.

10. The photovoltaic device of claim 1, wherein the substrate is transparent.

11. The photovoltaic device of claim 1, wherein the first and second plurality of structures are of the same composition as the substrate.

12. The photovoltaic device of claim 1, wherein the first and second plurality of structures and the substrate form a single crystal.

13. The photovoltaic device of claim 1, wherein a top portion of the first and second plurality of structures is rounded or tapered.

14. The photovoltaic device of claim 3, wherein the one or more junctions are selected from a group consisting of a p-i-n junction, a p-n junction, and a heterojunction.

15. The photovoltaic device of claim 1, wherein the first plurality and the second plurality of structures comprise nanowires.

16. The photovoltaic device of claim 1, further comprising a cladding layer.

17. The photovoltaic device of claim 1, wherein reflective layer is non-planar.

18. The photovoltaic device of claim 1, further comprising a cladding layer.

19. The photovoltaic device of claim 18, wherein the cladding layer is substantially transparent to visible light with a transmittance of at least 50%; the cladding layer is made of an electrically conductive material; the cladding layer is a transparent conductive oxide; the cladding layer is a material selected from a group consisting of indium tin oxide, aluminum doped zinc oxide, zinc indium oxide, Si₃N₄, Al₂O₃, and HfO₂, and zinc tin oxide; the cladding layer has a thickness from 10 nm to 500 nm; and/or the cladding layer is configured as an electrode of the photovoltaic device.

20. The photovoltaic device of claim 1, wherein the reflective layer is an electrically conductive material; the reflective layer has a reflectance of at least 50% for visible light; the reflective layer has a thickness from about 20 nm to about 500 nm; and/or the reflective layer is an electrode of the photovoltaic device.

21. The photovoltaic device of claim 3, further comprising a surface passivation layer configured to passivate the one or more junctions.

22. The photovoltaic device of claim 21, wherein one or more junctions comprise an exposed area not covered by the surface passivation layer.

23. A method of converting light to electricity comprising:
exposing a photovoltaic device to light, wherein the photovoltaic device comprises a substrate, a first plurality of structures essentially perpendicular to the substrate and disposed on a first face of the substrate, and a second plurality of structures essentially perpendicular to the substrate and disposed on a second face of the substrate;
drawing an electrical current from the photovoltaic device.

24. A photo detector comprising the photovoltaic device of claim 1, wherein the photo detector is configured to output an electrical signal when exposed to light.

25. A method of detecting light comprises:
exposing the photovoltaic device of claim 1 to light;
measuring an electrical signal from the photovoltaic device.

26. The method of claim 25, wherein the electrical signal is an electrical current, an electrical voltage, an electrical conductance and/or an electrical resistance.

27. The photovoltaic device of claim 1, wherein the first plurality and the second plurality of structures comprise microwires.
